(19) United States
(12) Patent Application Publication
(10) Pub. No.: US 2010/0246241 A1
(43) Pub. Date: Sep. 30, 2010

(54) SEMICONDUCTOR DEVICE WITH SOURCE LINES EXTENDING IN A DIFFERENT DIRECTION

(75) Inventors: Akiyoshi SEKO, Chuo-ku (JP); Shuichi Tsukada, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/749,126

(22) Filed: Mar. 29, 2010

(30) Foreign Application Priority Data
Mar. 30, 2009 (JP) 2009-083179

(51) Int. Cl. G11C 11/00; G11C 8/08

(52) U.S. Cl. 365/148; 365/230.06

(57) ABSTRACT

A semiconductor device includes a plurality of word lines extending in a first direction, a plurality of bit lines extending in a second direction, a plurality of source lines formed along a third direction which is different from the first and the second directions, and a source line control circuit serving as a driving arrangement selectively driving the plurality of source lines.

This application is based upon and claims the benefit of priority from Japanese patent application No. 2009-083179, filed on Mar. 30, 2009, the disclosure of which is incorporated herein in its entirety by reference.

### BACKGROUND OF THE INVENTION

1. Field of the Invention

This invention relates to a semiconductor device, and more particularly, to a semiconductor device comprising source lines.

2. Description of Related Art

As a convention semiconductor device, a semiconductor device comprising a plurality of memory cells formed in a matrix fashion, word lines, bit lines, and source lines that are connected to the memory cells is known in the art (for example, WO 03/065377, JP-A-2007-234133, and JP-A-8-77773).

A semiconductor device of WO 03/065377 is a device where the source lines are disposed in parallel with the bit lines (data lines). Therefore, coupling capacitors are formed between the source lines selectively driven and the bit lines adjacent thereto. Accordingly, there is a problem that a driving speed of the source lines (specially, a discharge speed) is limited. This problem is similar to the semiconductor device of JP-A-2007-234133.

Inasmuch as the semiconductor device described in JP-A-8-77773 is a static random access memory (SRAM). It is therefore not necessary to drive the source lines. This is because it is a power source for a flip flop for holding information. Accordingly, JP-A-8-77773 neither discloses nor teaches the problem occurring by driving the source lines and means for resolving it.

### SUMMARY

The present invention seeks to solve one or more of the above problems, or to improve upon those problems at least in part.

In one embodiment, there is provided a device that includes a plurality of word lines each extending in a first direction, a plurality of bit lines each extending in a second direction, a plurality of source lines each being formed along a third direction which is different from the first and the second directions, a plurality of memory cells which are connected to points of intersection of the word lines, the bit lines, and the source lines, and a driving arrangement selectively driving the plurality of source lines which correspond to memory cells selected from the plurality of memory cells.

In another embodiment, there is provided a device that includes a plurality of memory cells arranged in a matrix fashion, a plurality of word lines connected in common to the plurality of memory cells which are arranged in a row direction, a plurality of bit lines connected in common to the plurality of memory cells which are arranged in a column direction, a plurality of source lines connected in common to the plurality of memory cells which are arranged in a diagonal direction different from the row and the column directions, and a driving arrangement selectively driving the plurality of source lines which correspond to memory cells selected from the plurality of memory cells.

In still another embodiment, there is provided a method that comprises controlling a device. The device includes a plurality of word lines extending in a first direction, a plurality of bit lines extending in a second direction, a plurality of source lines extending in a direction different from the first and second directions, and a plurality of memory cells connected to points of intersection of the word lines, the bit lines, and the source lines, respectively. Each of the memory cells includes a memory element storing information and a selection transistor selecting the memory element. The controlling comprises controlling the plurality of source lines to a first predetermined potential; controlling the source line corresponding to the memory cell of an access subject from the first predetermined potential to a second predetermined potential and controlling the selection transistor to activation; and controlling the corresponding source line from the second predetermined potential to the first predetermined potential after sensing of the memory cell and controlling the selection transistor to inactivation.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a view showing schematic structure of a main portion of a semiconductor device according to a first exemplary embodiment of this invention;

FIG. 2 is an enlarged view of an area A of FIG. 1;

FIG. 3 is an enlarged view of a selected cell and a non-selected cell positioned adjacent thereto in the semiconductor device of FIG. 1;

FIG. 4 is a time chart for use in describing operation of the semiconductor device illustrated in FIG. 1;

FIG. 5A is a view showing relationship between word lines, bit lines, and source lines and word addresses, bit addresses, and source addresses;

FIG. 5B is an address table showing address makeup thereof:

FIG. 6A is a view showing an internal structure of a bit line controller or a source line controller included in the semiconductor device illustrated in FIG. 1;

FIG. 6B is a view showing an internal structure of a word line driver included in the semiconductor device illustrated in FIG. 1;

FIG. 7A is a circuit diagram showing an internal structure of an address decoder portion shown in FIG. 6A or FIG. 6B;

FIG. 7B is a truth table showing an input/output relationship thereof;

FIG. 8 is a circuit diagram showing an internal structure of a source address generator included in the semiconductor device illustrated in FIG. 1;

FIG. 9A is a view showing structure of a semiconductor device according to a second exemplary embodiment of this invention and a view showing relationship between word lines, bit lines, and source lines and word addresses, bit addresses, and source addresses;

FIG. 9B is an address table showing address makeup thereof:

FIG. 10A is a view showing structure of a semiconductor device according to a third exemplary embodiment of this invention and a view showing relationship between word lines, bit lines, and source lines and word addresses, bit addresses, and source addresses;

FIG. 10B is an address table showing address makeup thereof:

FIG. 11A is a view showing structure of a semiconductor device according to a fourth exemplary embodiment of this invention and a view showing relationship between word lines, bit lines, and source lines and word addresses, bit addresses, and source addresses;

FIG. 11B is an address table showing address makeup thereof:

FIG. 12 is a view showing structure of a semiconductor device according to a fifth exemplary embodiment of this invention and a view showing relationship between word lines, bit lines, and source lines and word addresses, bit addresses, and source addresses;

FIG. 13A is a circuit diagram showing a structure example of an address decoder for use in the semiconductor device illustrated in FIG. 12;

FIG. 13B is a circuit diagram showing another structure example of an address decoder for use in the semiconductor device illustrated in FIG. 12;

FIG. 14A is a view showing structure of a semiconductor device according to a sixth exemplary embodiment of this invention and a view showing relationship between word lines, bit lines, and source lines and word addresses, bit addresses, and source addresses;

FIG. 14B is an address table showing address makeup thereof:

FIG. 15A is a view showing structure of a semiconductor device according to a seventh exemplary embodiment of this invention and a view showing relationship between word lines, bit lines, and source lines and word addresses, bit addresses, and source addresses;

FIG. 15B is an address table showing address makeup thereof:

FIG. 16A is a view showing structure of a semiconductor device according to an eighth exemplary embodiment of this invention and a view showing relationship between word lines, bit lines, and source lines and word addresses, bit addresses, and source addresses;

FIG. 16B is an address table showing address makeup thereof: and

FIG. 17 is a view showing structure of a semiconductor device according to a ninth exemplary embodiment of this invention and a view showing relationship between word lines, bit lines, and source lines and word addresses, bit addresses, and source addresses.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Specifically, a semiconductor device of this invention comprises a plurality of word lines each extending in a first direction, a plurality of bit lines each extending in a second direction, a plurality of source lines formed along a third direction that is different from the first and the second directions, and a source line control circuit serving as a driving arrangement for driving the plurality of source lines.

Alternatively, a semiconductor device of this invention comprises a plurality of memory cells arranged in a matrix fashion, a plurality of word lines connected in common to the memory cells aligned in a row direction, a plurality of bit lines connected in common to the memory cells aligned in a column direction, a plurality of source lines connected in common to the memory cells aligned in a diagonal direction, and a source line control circuit serving as a driving arrangement for driving the plurality of source lines.

The source line control circuit sets source electrodes of selection transistors to a predetermined potential in a collective manner with respect to alignment of one or more memory cells aligned in the third direction so that a control unit becomes a predetermined number of the memory cells. Furthermore, the source line control circuit makes the predetermined number equal to a maxim number among the number of the memory cells aligned along the third direction.

A word line driving arrangement for activating the word lines maintains an activated (ON; conducting) state of the selection transistors for selecting memory elements at a predetermined time interval after accessing of memory cells and carries out initialization for a next access by recharging nodes of both ends of the memory elements to the predetermined potential from constant voltage sources provided to the bit lines and the source lines, respectively.

Now, the description will be made about exemplary embodiments of this invention with reference to the drawings.

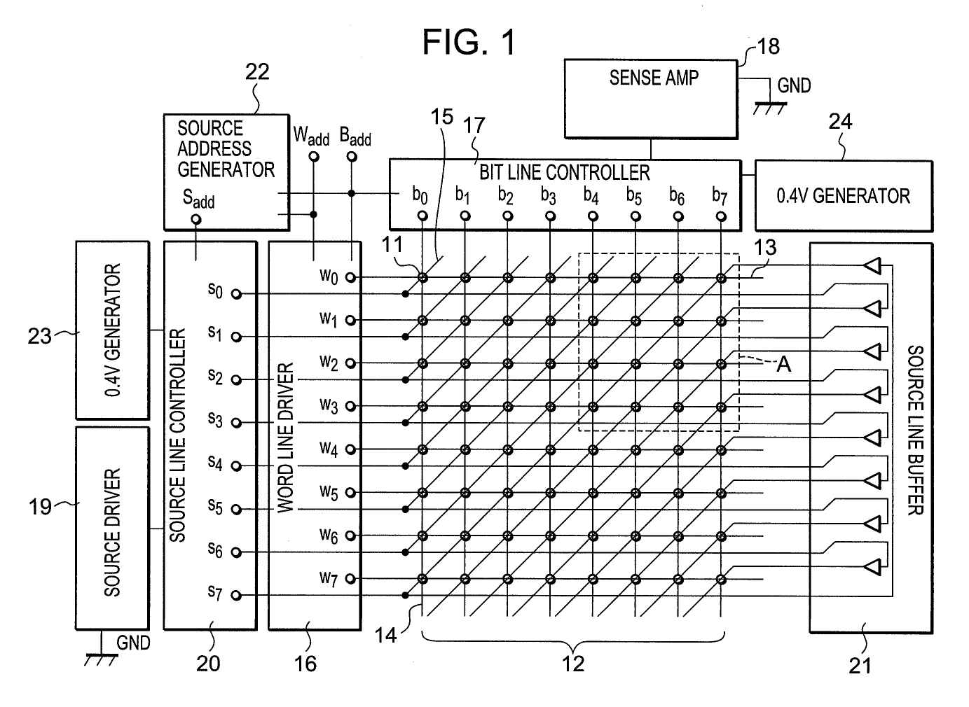

FIG. 1 shows a schematic structure of a main portion of a semiconductor device according to a first exemplary embodiment of this invention.

The illustrated semiconductor device comprises a cell array portion comprising a plurality of memory cells 11 (which are denoted by circles) arranged in a matrix fashion (in a square array structure with 8 rows and 8 columns (8×8) in this embodiment), a plurality of (eight in this embodiment) word lines 13, a plurality of (eight in this embodiment) bit lines 14, a plurality of (fifteen in this embodiment) source lines 15 which are connected to the memory cells 11, a word line driver 16, a bit line controller 17, a sense amplifier 18, a source driver 19, a source line controller 20, a source line buffer 21, a source address generator 22, a first constant voltage source (0.4V generator) 23, and a second constant voltage source (0.4V generator) 24. The first voltage source 23 and the second voltage source 24 may be shared.

Although the structure of the memory array portion 12 comprises the square array structure with 8 rows and 8 columns in this embodiment, the structure of the memory array portion 12 may comprise any array structure with M rows and N columns, where M represents a first positive integer which is not less than two and N represents a second positive integer which is not less than two. In this event, the plurality of word lines 13 are equal in number to M while the plurality of bit lines 14 are equal in number to N. The plurality of source lines 15 are equal in number to L, where L represents a third positive integer which is not less than two. The third positive integer L is equal to (M+N−1). The L source lines 15 are arranged without overlapping with respect to the (M×N) memory cells 11.

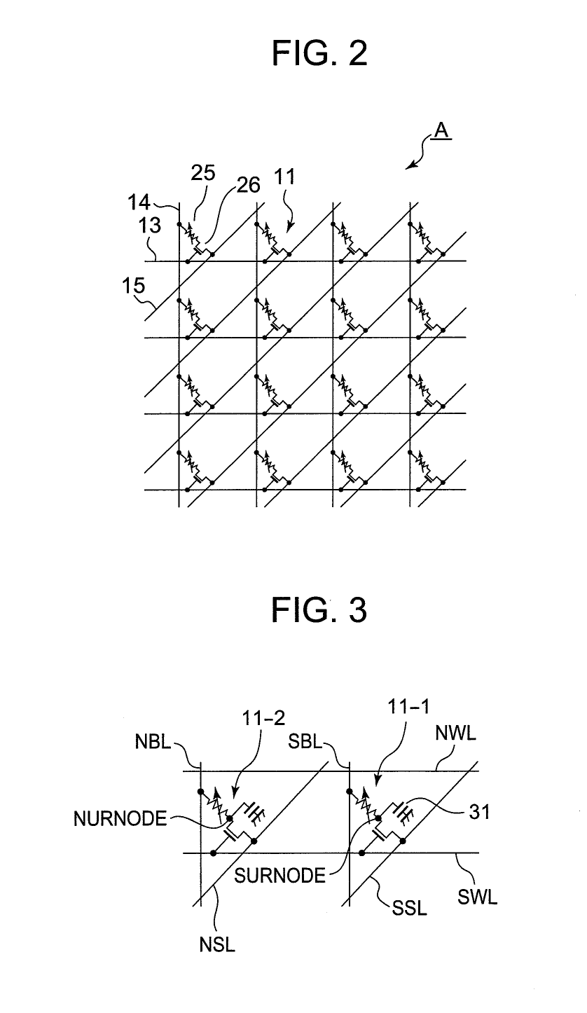

FIG. 2 is an enlarged view showing an area A enclosed in a broken line of FIG. 1. As shown in FIG. 2, each of the memory cells 11 comprises a phase-change resistor element (a variable resistor body) 25 and a selection transistor 26. The phase-change resistor element 25 comprises an element using a substance which exhibits a different resistor state according to a phase state such as chalcogenide glass or the like. In addition, the selection transistor 26 comprises an N-channel metal oxide semiconductor (NMOS) transistor. That is, the semiconductor device according to this exemplary embodiment comprises a memory device called a Phase change Random Access Memory (PRAM).

The phase-change resistor element 25 has an end connected to the bit line 13 and another end connected to a drain electrode of the selection transistor 26. In addition, the selection transistor 26 has a gate electrode connected to the word line 13 and a source electrode connected to the source line 15.

Turning back to FIG. 1, the memory cells 11 aligned in a left-right direction (the first direction or the row direction) in this figure are connected to a common word line 13. In addition, the memory cells 11 aligned in up and down (the second direction or the column direction) in this figure are connected to a common bit line 14. Furthermore, the memory cells 11 aligned in a diagonal direction (the third direction or a direction from up-right to down-left) in this figure are connected to a common source line 15. With this structure, the memory cells 11 connected to the common source line 15 are connected to the word lines 13 and the bit lines 14 which are different from each other. In addition, each source line 15 extends along a direction which are different from any of extending directions of the word lines 13 and the bit lines 14 and which is not in parallel with the extending directions thereof. In addition, connection lines for connecting the source line controller 20 with the source line buffer 21 extend in the same direction in which the word lines 13 extend but extend in a direction different from a direction in which the bit lines 14 extend.

The word line driver 16 selectively drives one of the word lines 13 that is designated by a word line address Wadd in accordance with a command input from an external device.

The bit line controller 17 selects one of the bit lines 14 that is designated by a bit line address Badd in accordance with a command input from the external device. On standby, the bit line controller 17 supplies the selected bit line 14 with a constant voltage (for example, 0.4 volts) generated by the second constant voltage source 24. On reading out of, the bit line controller 17 connects the selected bit line 14 with the sense amplifier 18.

The sense amplifier 18 detects a potential of the bit line to amplify the detected potential.

The source line controller 20 selects (a group of) the source line or lines 15 that is designated by a source line address Sadd in accordance with a command input from the external device. On standby, the source line controller 20 supplies (groups of) the non-selected (all) source lines 15 with a constant voltage (for example, 0.4 volts) generated by the first constant voltage source 23. On reading out of, the source line controller 20 connects (the group of) the selected source line or lines 15 with the source driver 19.

The source line buffer 21 comprises a plurality of buffer (signal amplifying) circuits. The source line buffer 21 mutually connects the source lines 15 via the buffer circuits so that the memory cells having the number equal to the maximum number among the memory cells connected to each course line 15 become a control unit by the source line control circuit 20. Herein, inasmuch as the memory cells are arranged in a square matrix fashion (a square array structure), the number of the memory cells that are connected to the source line corresponding to the diagonal line are equal to eight which is the maximum. Therefore, the source line numbered i (=1˜7) from the up-left is connected to the source line numbered (i+8). Thereby, the source line controller 20 controls eight groups of source lines 15 each of which is connected to eight memory cells 11.

The source line buffer 21 serves as a source line driving arrangement together with the source line controller 20, the source driver 19, and the first constant voltage source 23. Throughout the whole of the specification, a term of “driving” means to set source lines or the like to a predetermined potential and includes not only a case of setting it to a specific potential of positive or negative but also a case of setting it to a ground (GND) level.

Now, the description will be made about operation of the semiconductor device illustrated in FIG. 1. Herein, the memory cell 11 serving as a readout subject is called a selected cell while the memory cells other than it are called non-selected cells.

FIG. 3 shows the selected cell depicted at 11-1 and the non-selected cell depicted at 11-2 adjacent thereto. In the manner which is described above, each memory cell 11 comprises the phase-change resistor element 25 and the selection transistor 26. There is a parasitic capacitor (a variable resistor lower capacitor) 31 at a connection point (a variable resistor lower node) therebetween. The phase-change resistor element 25 has a resistance value set into a high resistance state and a low resistance state which correspond to “0” and “1” of the memory cell information, respectively. In the following description, the word line 13, the bit line 14 and (the group of) the source line or lines 15 which are connected to the selected cell 11-1 are called a selected word line SWL, a selected bit line SBL, and a selected source line or lines SSL, respectively. In addition, the word lines 13 except for the selected word line SWL, the bit lines 14 except for the selected bit line SBL, and (the group of) the source lines 15 except for the selected source line or lines SSL are called non-selected word lines NWL, non-selected bit lines NBL, and non-selected source lines NSL, respectively. Furthermore, the variable resistor lower node of the selected cell 11-1 is depicted at SURNODE while the variable resistor lower node of the non-selected cell 11-2 is depicted at NURNODE.

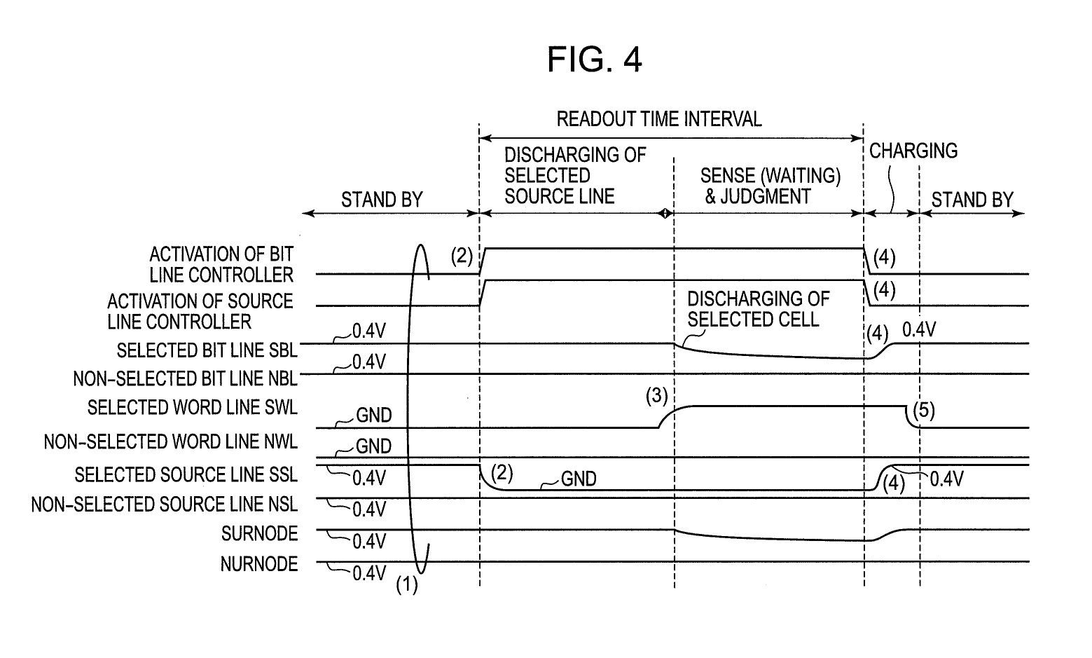

Referring now to a flow chart of FIG. 4, the description will be made about operation of the semiconductor device illustrated in FIG. 1. Herein, numbers in parenthesis in the following correspond to numbers in parenthesis in FIG. 4.

(1) On standby, all of bit lines 14 (SBL and NBL) are connected to the second constant voltage source 24 via the bit line control circuit 17 and are charged (pre-charged) to the constant voltage (herein, 0.4 volts). Similarly, all of the source lines 15 (SSL and NSL) are connected to the first constant voltage source 23 via the source line controller 20 and charged (pre-charged) to the constant voltage (herein, 0.4 volts).

(2) When an cell address for the memory cell serving as the readout subject is given and the source line control circuit 20 is activated, the source line controller 20 connects the selected source line SSL to the source driver 19 and removes electric charges of the selected source line SSL to maintain a potential thereof to the ground potential. In this event, the non-selected source line NSL is maintained to the pre-charged voltage (0.4 volts). Inasmuch as the selected source line SSL is inclined in the slanting direction with respect to the bit line which is pre-charged, there is a minimal coupling capacitor. Therefore, removal of the electric charges from the selected source line SSL is carried out at a relatively high speed and comes to end at a short time interval. As a result, it is possible to speeds up a starting of the next process in comparison with the prior art.

Concurrently with activation of the source line controller 20, the bit line controller 17 is also activated, and the bit line controller 17 connects the selected bit line SBL to the sense amplifier 18.

(3) After a lapse of a necessary time interval when the selected source line SSL reaches to the ground potential GND, the word line driver 16 is activated and the word line driver 16 puts the selection transistor 26 of the selected cell 11-1 into an ON (conducting) state. The selected bit line SBL becomes a ground state via the phase-change resistor element 25 and a potential of the selected bit line SBL is reduced toward the ground potential. A potential reduction speed of the selected bit line SBL is determined by the resistance value (the stored information) of the phase-change resistor element 25. Accordingly, it is possible to decides whether the phase-change resistor element 25 has the high resistance or the low resistance (whether the phase-change resistor element 25 stores information “0” or information “1”) by detecting the potential (a potential reduced amount) of the selected bit line after a lapse of a predetermined time interval from when the selection transistor 26 is turned on. The sense amplifier 18 detects the potential reduced amount by differential amplifying or the like and carries out a decision (reads out of the cell information).

(4) Next, the source line controller 20 and the bit line controller 17 are inactivated to turn the selected bit line SBL and the selected source line SSL back to a state similar to a case of the non-selected ones. Therefore, the selected bit line SBL and the selected source line SSL are connected to the second and the first constant voltage sources 24 and 23 via the bit line controller 17 and the source line controller 20, respectively, and are charged up to the pre-charge voltage (0.4 volts) again. In this event, inasmuch as the selected word line SWL leaves the activated (ON; conducting) state even now, the variable resistor lower node SURNODE of the selected cell 11-1 is enable to charge from the selected source line SSL side. Therefore, even if there is no electric charge moving from the selected bit line SBL in a case where the phase-change resistor element 25 is the high resistance, it is possible to charge the variable resistor lower capacitor 31 at a relatively high speed and it is possible to complete a charging at a short time.

(5) Finally, the word line driver 16 inactivates (turns off; non-conducts) the selected word line SWL. Thereby, the semiconductor device is turned back to a standby state.

In the manner which is described above, the semiconductor device according to this exemplary embodiment is operable at a high speed. This is because the bit line and the source line are charged to the pre-charged potential on standby and it is unnecessary to charge the bit line and the variable resistor lower capacitor 31 on selecting the memory cell.

In addition, inasmuch as there is little coupling capacitor between the selected source line SSL and the bit line 14 in the semiconductor device according to this exemplary embodiment, it is possible to carry out the driving (charging/discharging) of the selected source line SSL at a high speed. Furthermore, inasmuch as the selected word line SWL is put into the activated (ON; conducting) state on pre-charging the selected bit line SBL and the selected source line SSL again in the semiconductor device, it is possible to charge the variable resistor lower node SURNODE and the variable resistor lower capacitor 31 from the source line side in a case where the phase-change resistor element 25 of the selected cell has the high resistance and it is therefore possible to carry out the pre-charging thereof at a high speed and at a short time. Thus, it is possible to realize improvement of an access speed in the semiconductor device according to this exemplary embodiment. In addition, there is little generation of noises due to the coupling capacitor between the bit line and the source line. Furthermore, inasmuch as all of the bit lines SBL/NBL and all of the source lines SSL/NSL are charged (pre-charged) to the constant voltage (herein, 0.4 volts) on standby, there is no off-leak current in the selection transistor 26. Specifically, in a case of a three-dimensional memory cell array (the cell array portion 12 is laminated) where the selection transistor 26 is composed of a Thin Film Transistor (TFT) having a relatively large off-leak current value, this system is effective.

Inasmuch as the unit of control carrying out charging/discharging of the source lines 15 is equal to eight memory cells (the same number) in the semiconductor device according to this exemplary embodiment, the source driver 18 can drive any source line 15 at the same driving ability. In addition, inasmuch as the number of the groups of the source lines 15 are equal to the number of the bit lines 14 in the similar in prior art, it does not result in increase of the number of the source line driver and complication of the address decoder. Furthermore, inasmuch as the buffer circuit generally has a smaller layout area compared with that of the address decoder, it is possible to become smaller a chip area compared with a case where another source control circuit is provided in lieu of the source buffer 21 so as to control the source lines 15 independently.

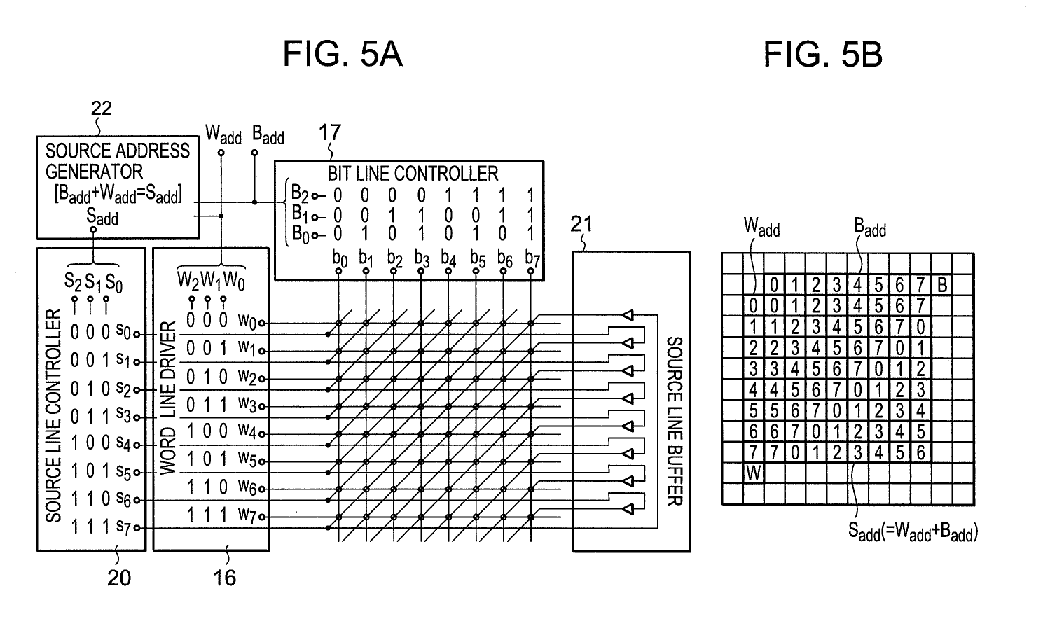

Referring now to FIGS. 5A and 5B, the description will be made as regards address makeup of the word lines 13, the bit lines 14, and the source lines 15. In addition, the following description notes one portion of the memory array and therefore address makeup of the whole of the chip such as the unit of a page, the unit of a mat, the unit of a bank, or the like may be arbitrarily set.

As shown in FIGS. 5A and 5B, it will be assumed that addresses Wadd and Badd each consisting of 3 bits (0 to 7 (decimal)) are assigned to the word lines 13 and the bit lines 14, respectively. In this event, the source address generator 22 calculates a sum (Badd+Wadd) of the addresses Wadd and Badd to produce it as the source line address Sadd. It is therefore possible to select (the group of) the source line or lines 15 without preparing source line dedicated addresses. Although the number of memory cells is high or low, it is possible to generate the source address based on the word address and the bit address in the manner which is described above. In addition, when the array configuration is not only square but also rectangle, it is possible to generate the source address based on the word address and the bit address in the manner which is described above.

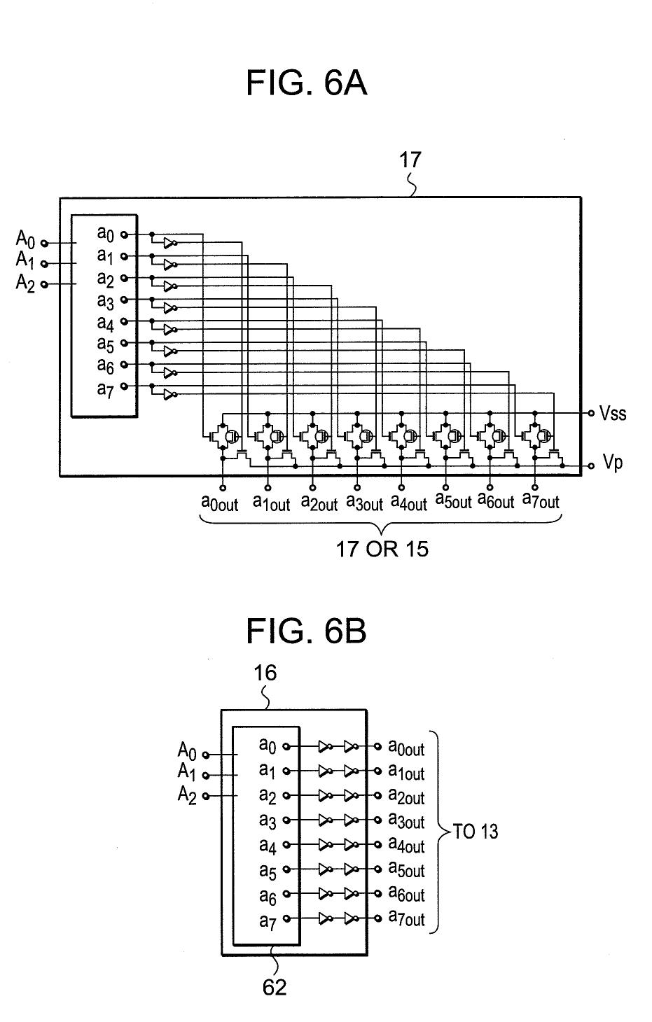

The bit line controller 17 and the source line controller 20 may be realized as a circuit including an address decoder portion 61 as shown, for example, in FIG. 6A. This circuit is mainly configured by using MOS transistors (NMOS (N channel MOS transistors) and PMOS (P channel MOS transistors)). Herein, it shows a case where a power supply voltage Vss is supplied to the source line or the bit line selected by an input address and a pre-charge voltage Vp is supplied to the source lines and the bit lines other than it. In addition, the word line driver 16 is realized by a circuit including an address decoder portion 62 as shown, for example, in FIG. 6B.

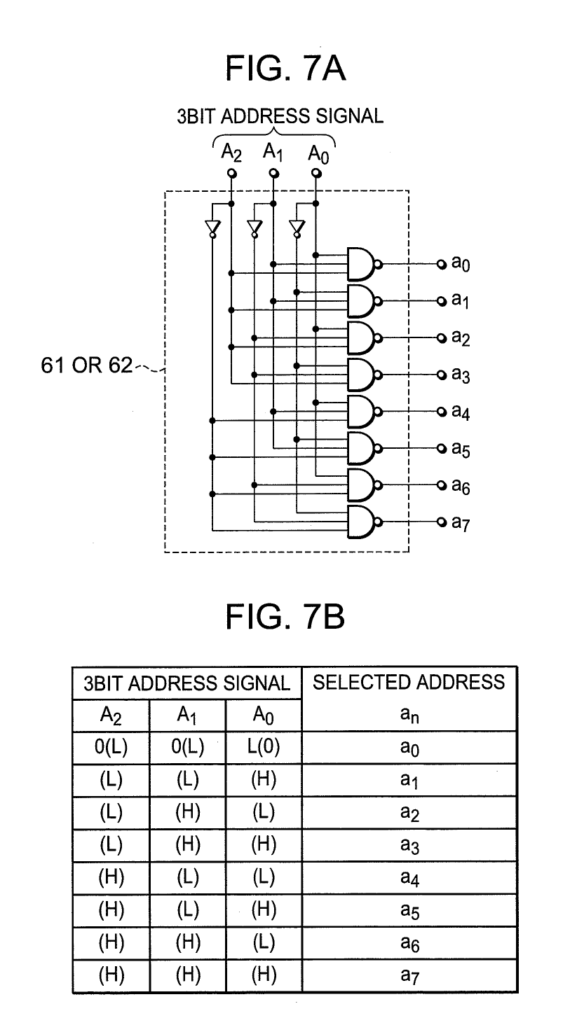

The address decoder portions 61, 62 used in each of the bit line controller 17, the source line controller 20, and the word line driver 16 may be realized by a circuit as shown, for example, in FIG. 7A. An input/output relationship of this circuit is like shown in FIG. 7B. When the number of input bits is four or more bits, similar construction may be expanded. Alternatively, a hierarchical structure may be adopted.

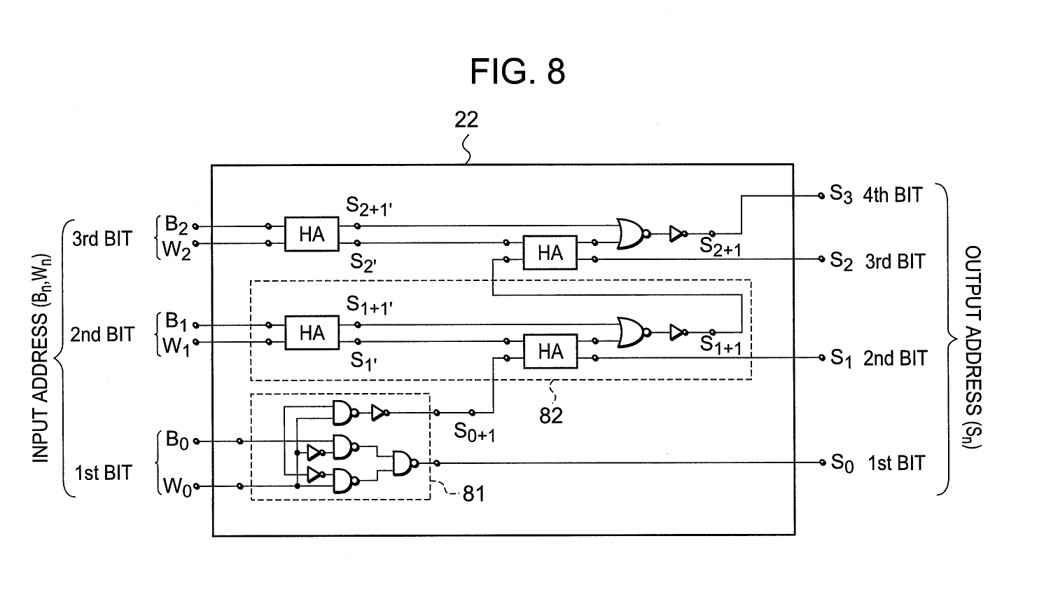

The source address generator 22 may be realized by using half-adders (HAs) 81 and full adders 82 as shown, for example, in FIG. 8. In addition, if an output of a fourth bit is unnecessary, it may be neglected. In addition, when the number of address bits is four or more, it may be adaptable by increasing the full adders.

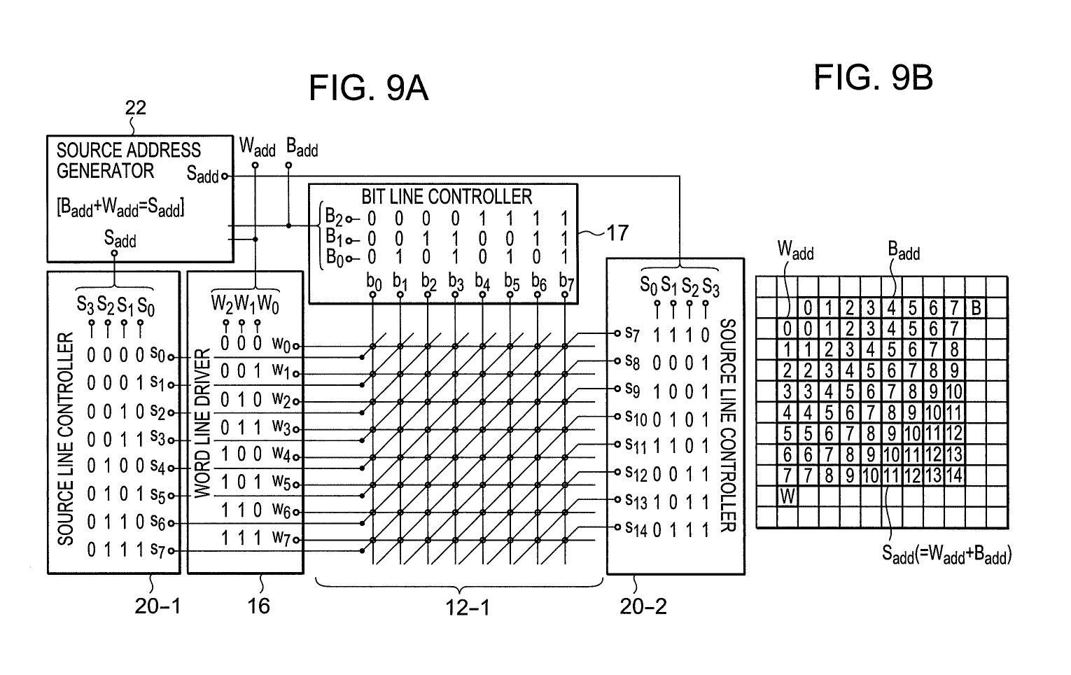

Referring now to FIGS. 9A and 9B, the description will proceed to a semiconductor device according to a second exemplary embodiment of this invention.

In the first exemplary embodiment, the source line 15 is connected to the source line controller 20 and the source line buffer 21 and it is configured so that the unit of control becomes the memory cells having the same number. As compared with this, the semiconductor device according to the second exemplary embodiment comprises a pair of source line controllers 20-1 and 2-2 as shown in FIG. 9A.

With this structure, structure of a cell array portion 12-1 is simplified and each source line 15 has little coupling capacitor with respect to not only the bits lines 14 but also the word lines 13. Accordingly, it is possible to further suppress generation of noises than a case of the first exemplary embodiment.

In addition, address makeup of the source lines 15 is like as shown in FIG. 9B.

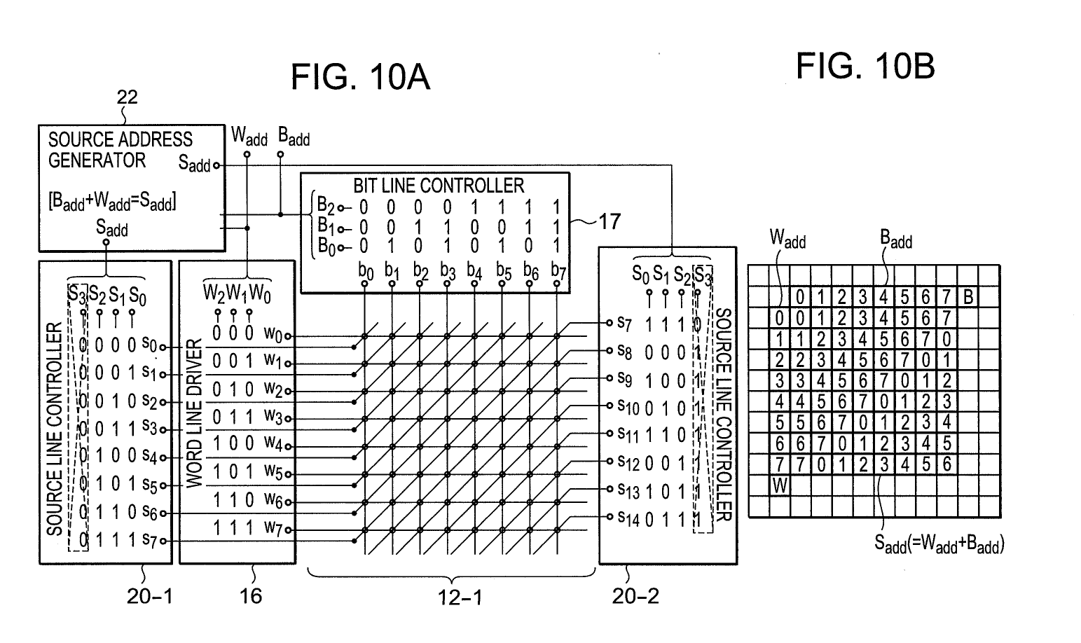

Referring now to FIGS. 10A and 10B, the description will proceed to a semiconductor device according to a third exemplary embodiment of this invention.

A point different from the second exemplary embodiment is a point carrying out address makeup of the source lines, as shown in FIGS. 10A and 10B. When the source line address Sadd is generated based on the bit line address Badd and the word line address Wadd, it is possible to make the unit of control the memory cells having the same number by doing not carry out carry calculation of third digit or by neglecting the maximum digit obtained in the similar manner in a case of the first exemplary embodiment. In addition, inasmuch as it is unnecessary to process an address signal of a fourth digit, it is possible to simplify structure of the source line controllers 20-1 and 20-2 compared with a case of the second exemplary embodiment.

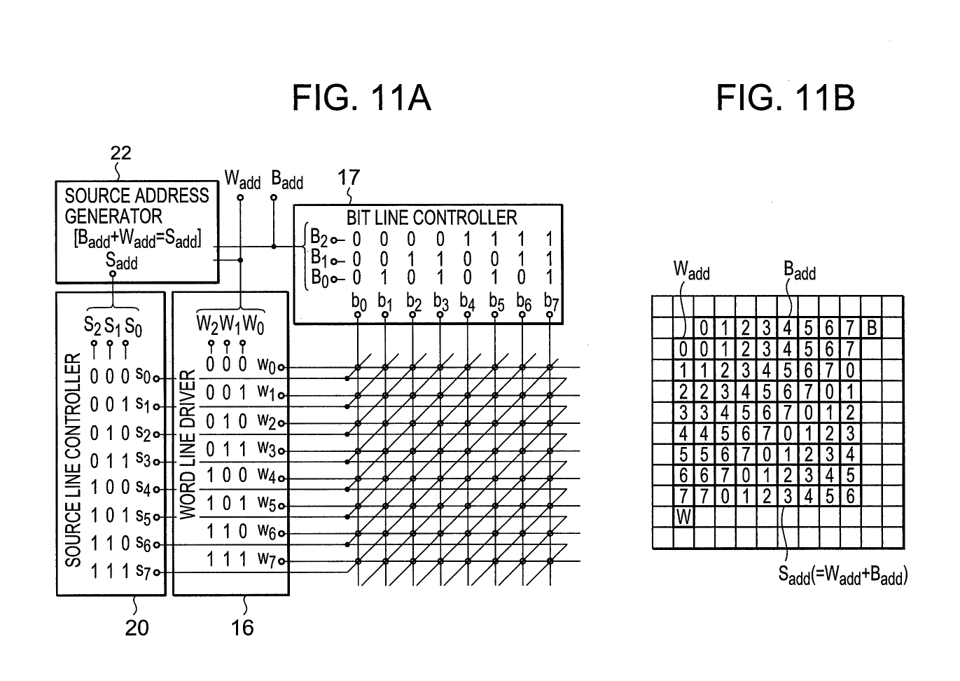

Referring now to FIGS. 11A and 11B, the description will proceed to a semiconductor device according to a fourth exemplary embodiment of this invention.

As is understood from FIG. 11A, the semiconductor device according to the fourth exemplary embodiment is different from the semiconductor device according to the first exemplary embodiment as regards having no source line buffer 22. Therefore, structure thereof is simplified. When the source driver 19 has a sufficient driving ability, such a structure is enable. FIG. 11B is a view showing address makeup of the source lines.

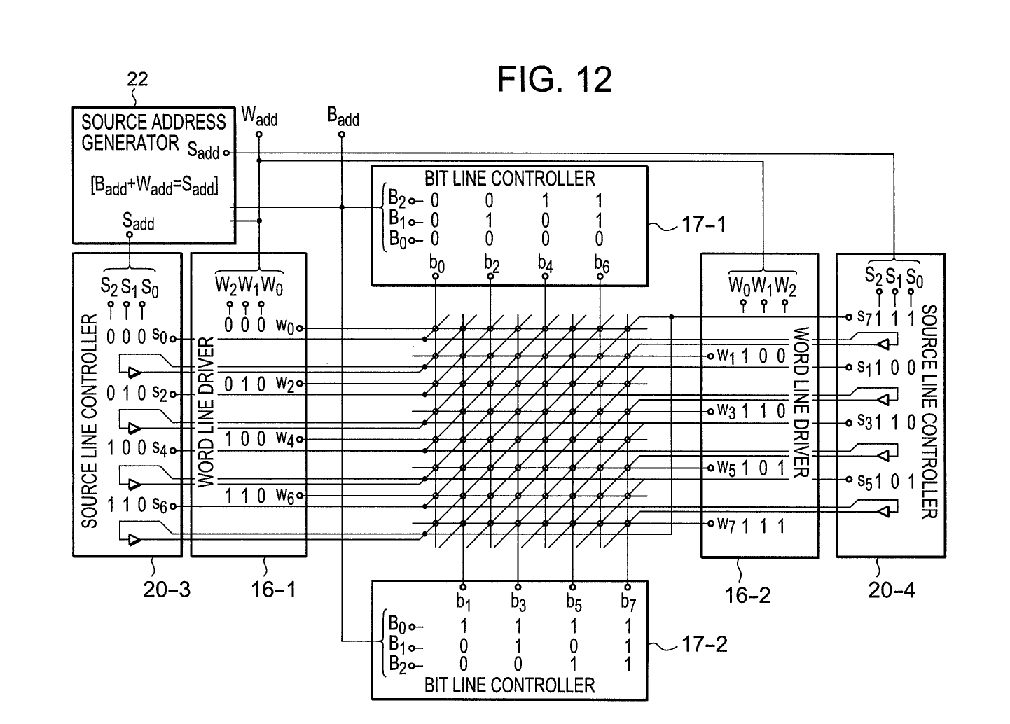

Referring now to FIG. 12, the description will proceed to a semiconductor device according to a fifth exemplary embodiment of this invention.

The semiconductor device according to the fifth exemplary embodiment comprises a pair of word line drivers 16-1 and 16-2, a pair of bit line controllers 17-1 and 17-2, and a pair of source line controllers 20-3 and 20-4. The adjacent word lines 13 are connected to the word line drivers which are different from each other. Likewise, the adjacent bit lines are connected to the bit line controllers which are different from each other. The adjacent source lines 15 are connected so as to be selectively driven from one source line controller side. That is, each line is connected to the driver or the controller in a staggered configuration

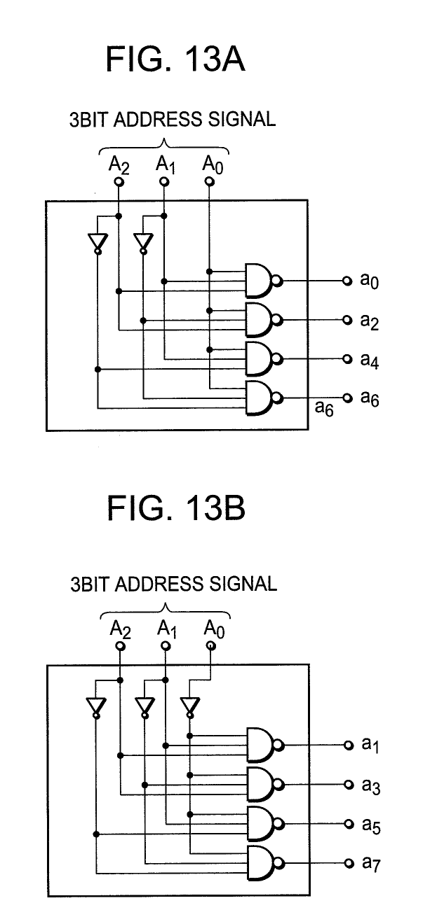

The address decoder circuits for use in this exemplary embodiment are configured as shown, for example, in FIGS. 13A and 13B. Each of those address decoder circuits is identical with one where a part is excerpted from the address decoder circuit 61 or 62 as shown in FIG. 7A. Specifically, the address decoder circuit as shown in FIG. 13A is one where a part corresponding to even addresses is excerpted while the address decoder circuit as shown in FIG. 13B is one where a part corresponding to odd addresses is excerpted.

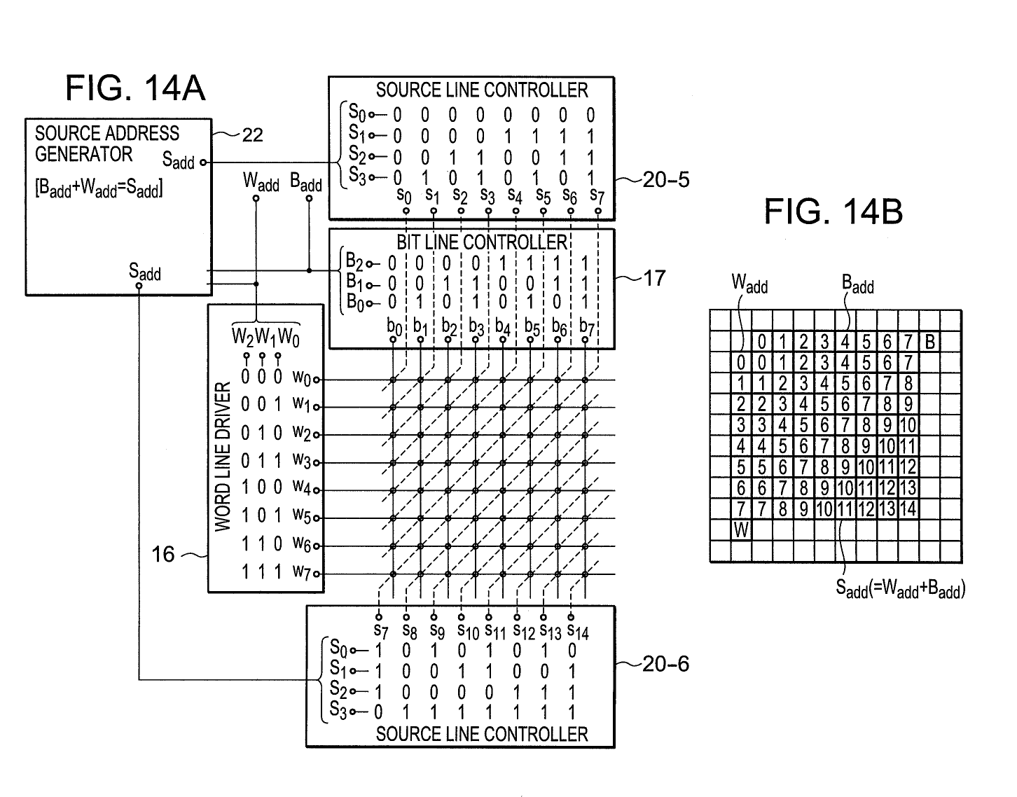

Referring now to FIGS. 14A and 14B, the description will proceed to a semiconductor device according to a sixth exemplary embodiment of this invention.

Although the source line controller 20 is arranged so as to align to the word driver in the afore-mentioned exemplary embodiment, in the semiconductor device according to the sixth embodiment, source line controllers 20-5 and 20-6 are arranged so as to align to the bit line controller 17 or to oppose thereto. FIG. 14B is a view showing address makeup of the source lines.

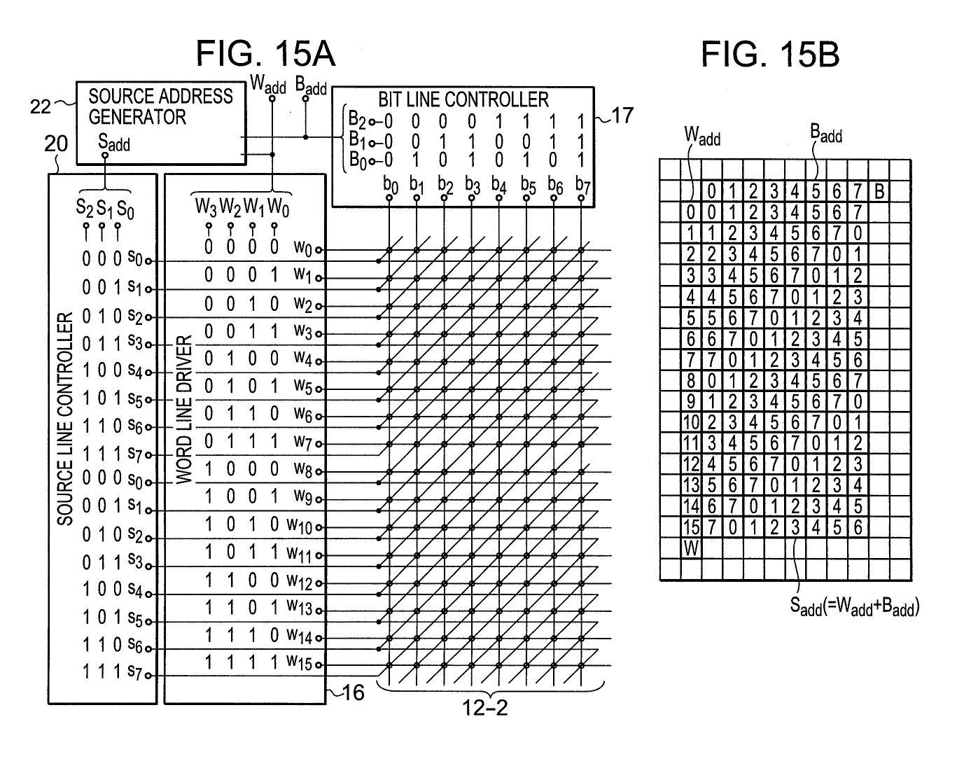

Referring now to FIGS. 15A and 15B, the description will proceed to a semiconductor device according to a seventh exemplary embodiment of this invention.

Although each of the semiconductor devices according to the afore-mentioned exemplary embodiments comprises the cell array portion 12 where memory cells are arranged in a square matrix fashion, the semiconductor device according to the seventh exemplary embodiment comprises a cell array portion (rectangular array configuration) 12-2 where memory cells are arranged in a rectangular matrix fashion (herein, with 16 rows and 8 columns) as shown in FIG. 15A. In the seventh exemplary embodiment, it makes sixteen memory cells the unit of control. In addition, address makeup of the source lines becomes as shown in FIG. 15B. On generating the source address, the source address generator 22 does not carry out calculation of a fourth digit and a fifth digit or neglects them.

In the manner which is described above, this invention can be applied to also the semiconductor device comprising a memory cell array of a rectangular array configuration which is longer in the column direction.

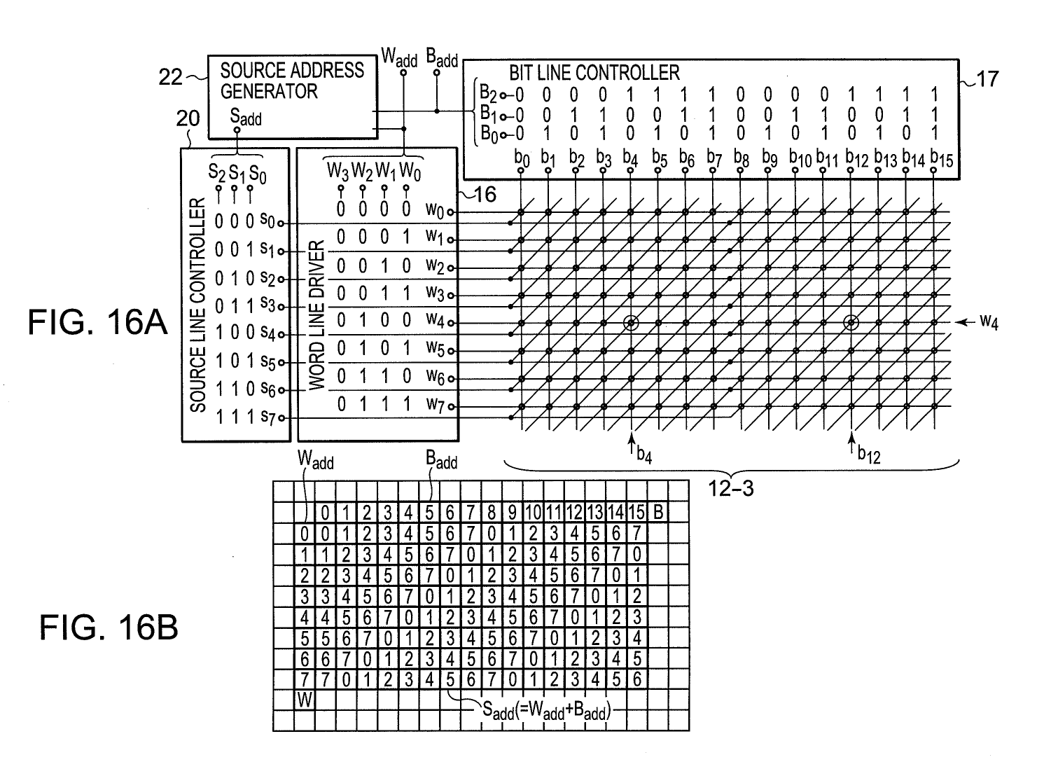

Referring now to FIGS. 16A and 16B, the description will proceed to a semiconductor device according to an eighth exemplary embodiment of this invention.

Although the semiconductor device according to the seventh exemplary embodiment comprises the cell array portion 12-2 of the rectangular matrix fashion which is longer in the column direction, the semiconductor device according to the eighth exemplary embodiment comprises a cell array portion 12-3 of a rectangular matrix fashion which is longer in the row direction, as shown in FIG. 16A. An address makeup of the source lines is like in shown in FIG. 16B.

In the semiconductor device according to the eighth exemplary embodiment, it is, for example, assumed that the memory cell corresponding to the word line w4 and the bit line b4 is selected. In this event, a current flows from the bit line to the source line (or the ground GND) in the memory cell corresponding to the word line w4 and the bit line b12. However, inasmuch as such short-circuited cells are in number low, it is possible to neglect. In this event, only the bit line b4 is connected to the sense amplifier 18 and the bit line b12 is not connected thereto. Such a distinction is enable by using an address of the fourth digit.

In the manner which is described above, this invention can be applied to the semiconductor device comprising the memory cell array of the rectangular cell array which is longer in the row direction also.

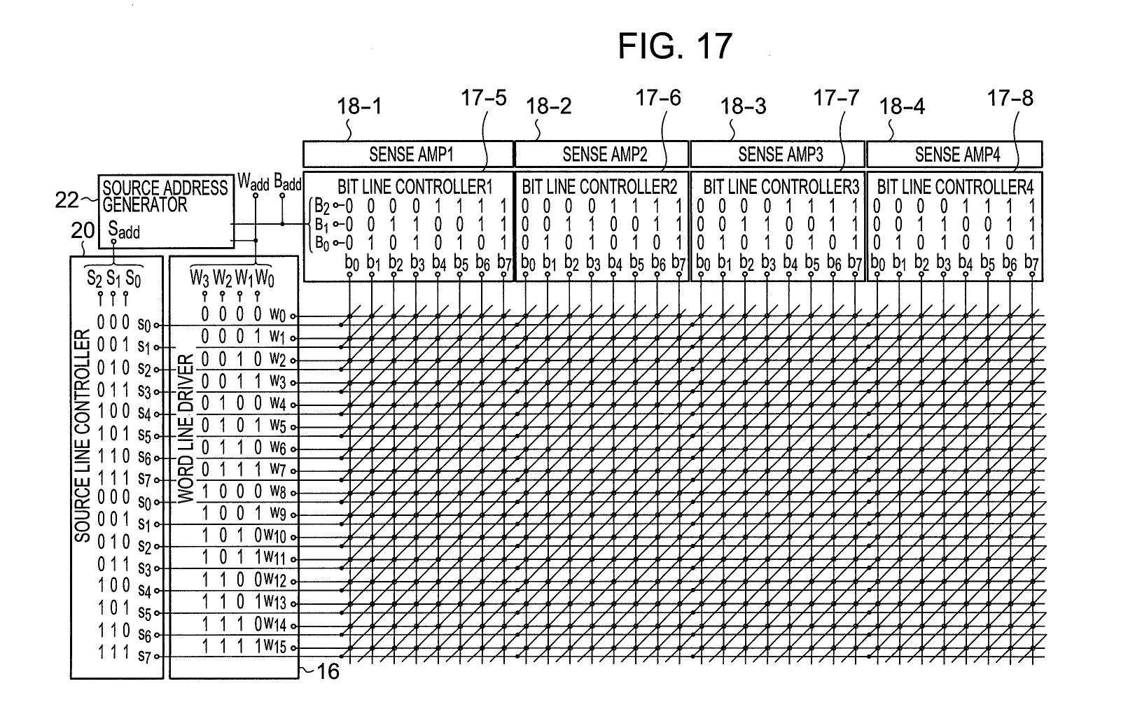

Referring now to FIG. 17, the description will proceed to a semiconductor device according to a ninth exemplary embodiment of this invention.

The semiconductor device according to the ninth exemplary embodiment comprises a plurality of (herein four) bit line controllers 17-5 to 17-8 and a plurality of (herein four) sense amplifiers 18-1 to 18-4. Reading out of data is carried out at a unit of the sense amplifiers

While the invention has been particularly shown and described with reference to exemplary embodiments thereof, the invention is not limited to these embodiments. It will be understood by those of ordinary skilled in the art that various changes in form and details may be made therein without departing from the sprit and scope of the present invention as defined by the claims.

For example, although the description is made about a case of PRAM in the above-mentioned exemplary embodiments, this invention may be applied to semiconductor devices for controlling a state of memory cells using three wires of the bit line, the word line, and the source line. In addition, this invention can be applied to not only the semiconductor device using the phase-change resistor elements but also semiconductor devices using resistance variable elements called resistance random access memories (ReRAMs). In addition, this invention can be applied to a volatile memory device storing memory information as changing of on resistance (conducting resistance) of (selection) transistors. There is a semiconductor memory device called, for example, a floating body memory such as a semiconductor memory device.

Although the description has been made as regards the semiconductor memory devices in the above-mentioned exemplary embodiments, this invention can provide to various logic devices, various semiconductor devices, various semiconductor systems each of which comprises memory cells. That is, a fundamental technical idea of this invention can be applied to various semiconductor devices without limiting to special-purpose memory devices. For example, this invention can be applicable to the semiconductor devices in general such as a CPU (Central Processing Unit), an MCU (Micro Control Unit), a DSP (Digital Signal Processor), an ASIC (Application Specific Integrated Circuit), an ASSP (Application Specific Standard Circuit) each comprising a plurality of memory elements as a memory function, and so on. A product form to which this invention is applicable can be applied to a SOC (System On Chip), an MCP (Multi Chip Package), a POP (Package On Package), or the like. This invention can be applied to the semiconductor devices having those any product forms or package forms.

Although the voltage of 0.4 volts is adopted as the pre-charge voltage in the above-mentioned exemplary embodiments, the pre-charge voltage can be set freely. For example, when a reference potential of the sense amplifier can be set to a negative voltage, it is possible to the pre-charge voltage to a ground potential. It is therefore possible to reduce consumed power. In this event, a potential of a selected source line is made to a negative potential (e.g. −0.4 volts) on reading out of.

Although the description has been made about examples each detecting that a discharging speed of the bit line differs due to a difference of the resistance value corresponding to information written in the memory cell in the afore-mentioned exemplary embodiments, conversely, it may detect a difference of a charging speed of the bit line due to the resistance value corresponding to information written in the memory cell.

Although the description has been made as regards a case of detecting a voltage change by the sense amplifier in the above-mentioned exemplary embodiments, structure of a voltage difference amplifying circuit used therein is specially not limited. In addition, it may detect a current change instead of the voltage change of the bit line.

Although MOS (Metal Oxide Semiconductor) transistors are used as transistors for use in each portion in the afore-mentioned exemplary embodiments, the transistors may be field effect transistors (FETs) and may use various transistors such as MIS (Metal-Insulator Semiconductor), TFT (Thin Film Transistor), or the like. In addition, it may use, as the transistors, bipolar transistors. Furthermore, an NMOS transistor (an N-channel MOS transistor is a typified example of a first conductive-type transistor while a PMOS transistor (a P-channel MOS transistor) is a typical example of a second conductive-type transistor.

Various combinations and selection of various disclosed elements can be available within the bounds of claims of this invention. Specifically, this invention certainly contains all of disclosures including claims, various modification and revisions which will be made by those skilled in the art.

What is claimed is:

1. A device comprising:
a plurality of word lines each extending in a first direction;
a plurality of bit lines each extending in a second direction;
a plurality of source lines each being formed along a third direction which is different from the first and the second directions;
a plurality of memory cells which are connected to points of intersection of the word lines, the bit lines, and the source lines; and
a driving arrangement selectively driving the plurality of source lines which correspond to memory cells selected from the plurality of memory cells.

2. The device as claimed in claim 1, wherein said driving arrangement selectively drives the plurality of source lines so that a unit of control becomes a predetermined number of memory cells.

3. The device as claimed in claim 2, wherein the predetermined number is equal to a maximum number among the number of memory cells connected to the plurality of source lines, respectively.

4. The device as claimed in claim 1, wherein each of said memory cells comprises:
a memory element storing information; and
a selection transistor connected to the memory element in series, said selection transistor being connected to one of the bit line and the source line,
wherein said device further comprises a word line driving arrangement connected to said selection transistor, said word line driving arrangement activating said selection transistor on charging said bit line and said source line into a predetermined potential, thereby charging nodes of both ends of said memory element to the predetermined potential from respective constant voltage sources connected to said bit lines and said source lines.

5. The device as claimed in claim 1, wherein each of said memory cells includes a memory element storing information and a selection element selecting said memory element,
wherein said memory element and said selection element are connected in series between said bit line and said source line.

6. The device as claimed in claim 1, wherein each of said memory cells includes a memory element storing information by a variable resistor element.

7. The device as claimed in claim 1, wherein said plurality of word lines are equal in number to M, said plurality of bit lines are equal in number to N, and said plurality of source lines are equal in number to L, where M represents a first positive integer which is not less than two, N represents a second positive integer which is not less than two, L presents a third positive integer which is not less than two, and
wherein said plurality of memory cells are equal in number to (M×N) and are arranged in vicinity of intersections between M word lines and N bit lines.

8. The device as claimed in claim 7, wherein the L source lines are arranged without overlapping with respect to the (M×N) memory cells.

9. A device comprising:
a plurality of memory cells arranged in a matrix fashion;
a plurality of word lines connected in common to said plurality of memory cells which are arranged in a row direction;
a plurality of bit lines connected in common to said plurality of memory cells which are arranged in a column direction;
a plurality of source lines connected in common to said plurality of memory cells which are arranged in a diagonal direction different from the row and the column directions; and
a driving arrangement selectively driving said plurality of source lines which correspond to memory cells selected from said plurality of memory cells.

10. The device as claimed in claim 9, wherein said driving arrangement selectively drives the plurality of source lines so that a unit of control becomes a predetermined number of memory cells.

11. The device as claimed in claim 10, wherein the predetermined number is equal to a maximum number among the number of memory cells connected to the plurality of source lines, respectively.

12. The device as claimed in claim 9, wherein each of said memory cells comprises:
a memory element storing information; and
a selection transistor connected to the memory element in series, said selection transistor being connected to one the bit line and the source line,
wherein said device further comprises a word line driving arrangement connected to said selection transistor, said word line driving arrangement activating said selection transistor on charging said bit line and said source line into a predetermined potential, thereby charging nodes of both ends of said memory element to the predetermined potential from respective constant voltage sources connected to said bit lines and said source lines.

13. The device as claimed in claim 9, wherein each of said memory cells includes a memory element storing information and a selection element selecting said memory element,
wherein said memory element and said selection element are connected in series between said bit line and said source line.

14. The device as claimed in claim 9, wherein each of said memory cells includes a memory element storing information by a variable resistor element.

15. A method comprising: controlling a device,
wherein said device comprises a plurality of word lines extending in a first direction, a plurality of bit lines extending in a second direction, a plurality of source lines extending in a direction different from said first and second directions, and a plurality of memory cells connected to points of intersection of said word lines, said bit lines, and said source lines, respectively, each of said memory cell including a memory element storing information and a selection transistor selecting said memory element,
said controlling comprising:
controlling said plurality of source lines to a first predetermined potential;
controlling said source line corresponding to said memory cell of an access subject from the first predetermined potential to a second predetermined potential and controlling said selection transistor to activation; and
controlling the corresponding source line from the second predetermined potential to the first predetermined potential after sensing of said memory cell and controlling said selection transistor to inactivation.

16. The method as claimed in claim 15, wherein controlling source electrodes of selection transistors to the first and the second predetermined potentials in a collective manner with respect to alignment in one or more memory cells aligned along the third direction so that a unit of control becomes a predetermined number of memory cells.

17. The method as claimed in claim 16, wherein said predetermined number is equal to a maximum number of the memory cells aligned along the third direction.

18. A method as claimed in claim 15, wherein the inactivation control of said selection transistors is carried out after controlling the corresponding source line from the second predetermined potential to the first predetermined potential.

19. The method as claimed in claim 15, wherein said memory element and said selection transistor are connected in series between said bit line and said source line.

20. The method as claimed in claim 15, wherein each of said memory cells stores information in accordance with a difference of a variable resistance value.
